(19) United States
(12) Patent Application Publication
(10) Pub. No.: US 2011/0133882 A1
(43) Pub. Date: Jun. 9, 2011

(54) Apparatus for detecting coordinates of an event within interest region, display device, security device and electronic blackboard including the same

(75) Inventors: Il Mo Jung, Pyeongtaek (KR); Yong Gyu Yoon, Seoul (KR); Jae Goon Aum, Suwon (KR); Won Jin Baek, Uiwang (KR)

(73) Assignee: SAMSUNG ELECTRO-MECHANICS CO., LTD., Suwon (KR)

(21) Appl. No.: 12/801,221

(22) Filed: May 27, 2010

(30) Foreign Application Priority Data
Dec. 4, 2009 (KR) 10-2009-0119664

(51) Int. Cl. G05B 19/00; H01L 31/16; G06K 9/60; G09G 5/00

(52) U.S. Cl. 340/5.7; 250/353; 382/103; 345/156

(57) ABSTRACT

There is provided an apparatus for detecting the coordinates of an event within an interest region including: a light source limiting an interest region; at least two light receiving units receiving reflected light of an event within the interest region; a reflector refracting the reflected light received in the light receiving units; and one image sensor on which the reflected light refracted on the reflector is image-formed, wherein the apparatus for detecting coordinates is configured of one module.

### CROSS-REFERENCE TO RELATED APPLICATIONS

This application claims the priority of Korean Patent Application No. 10-2009-0119664 filed on Dec. 4, 2009, in the Korean Intellectual Property Office, the disclosure of which is incorporated herein by reference.

### BACKGROUND OF THE INVENTION

1. Field of the Invention

The present invention relates to an apparatus for detecting coordinates of an event within an interest region that identifies the event and detects the coordinates corresponding thereto by detecting the event generated within the interest region using an image sensor, a display device, a security device, and an electronic blackboard including the same.

2. Description of the Related Art

An apparatus for detecting coordinates by sensing changes, etc. generated in an interest region has been very broadly used.

As a method for detecting the coordinates of a point touched on a display panel that is an interest region on a mobile communications terminal or other device, such as a cellular phone, a PDA, a notebook computer, etc., an ultrasonic wave type, an infrared ray type, a resistive type, an electrostatic capacitance type, etc. have been used. Recently, the electrostatic capacitance type has mainly been used.

Meanwhile, when the size of the display panel that is the interest region is large, a method for detecting the coordinates of the event using an imaging device such as a camera has been proposed.

Herein, the event, which is an action or a situation that is generated in an interest region, such as a touch, may be defined as a change of an image detected in an image sensor of the imaging device.

An apparatus for detecting an event within an interest region, according to the prior art, that detects the coordinates of the event, is configured to include two or more separated imaging devices to input image information of the event generated within the interest region and an image processing unit that processes the input image information.

When the two or more separated imaging devices are used and installed to face the interest region, there is a problem, in that they require a large installation space.

Further, since the information obtained from the separated imaging devices is transmitted to the image processing unit to be combined, there is a problem in that the information should be synchronized at the time of processing.

### SUMMARY OF THE INVENTION

An aspect of the present invention provides an apparatus for detecting coordinates of an event within an interest region that can process generated event image information by only one image sensor using at least two light receiving units.

An aspect of the present invention also provides a display device, a security device, and an electronic blackboard including an apparatus for detecting coordinates of an event within an interest region.

According to an aspect of the present invention, there is provided an apparatus for detecting the coordinates of an event within an interest region, including: a light source limiting an interest region; at least two light receiving units receiving reflected light of an event within the interest region; a reflector refracting the reflected light received in the light receiving units; and one image sensor on which the reflected light refracted on the reflector is image-formed, wherein the apparatus for detecting coordinates is configured of one module.

The light source of the apparatus for detecting the coordinates of the event within the interest region may include an infrared illuminant.

The light receiving unit of the apparatus for detecting the coordinates of the event within the interest region may function as an inlet that inputs the reflected light to the image sensor and may include an optical element.

The apparatus for detecting the coordinates of the event within the interest region may further include: an infrared filter disposed in the front or the rear of the light receiving unit and admitting only a predetermined frequency band of the infrared rays of the reflected light reflected from the event.

The infrared filter of the apparatus for detecting the coordinates of the event within the interest region may be coated or attached to the surface of the light receiving unit.

The image sensor of the apparatus for detecting coordinates may be an infrared sensor.

The apparatus for detecting the coordinates of the event within the interest region may further include: an image processing unit receiving image information input to the image sensor and processing data.

The image processing unit of the apparatus for detecting the coordinates of the event within the interest region may be configured of a module which is separate from that of the apparatus for detecting coordinates and may receive the image information input to the image sensor through wireless communication.

According to another aspect of the present invention, there is provided an apparatus for detecting the coordinates of an event within an interest region, including: a light source including an infrared illuminant; at least two light receiving units receiving reflected light of an event that reflects infrared light emitted from the light source and disposed so as to form a triangle with the event; a reflector disposed at the rear of the light receiving unit so as to refract the reflected light received in the light receiving units; and one image sensor on which the reflected light refracted on the reflector is image-formed.

The light receiving unit of the apparatus for detecting the coordinates of the event within the interest region may function as an inlet that inputs the reflected light into the image sensor and may include an optical element.

The apparatus for detecting the coordinates of the event within the interest region may further include: an infrared filter disposed in the front or the rear of the light receiving unit and admitting only a predetermined frequency band of the infrared rays of the reflected light from the event.

The infrared filter of the apparatus for detecting the coordinates of the event within the interest region may be coated or attached to the surface of the light receiving unit.

The image sensor of the apparatus for detecting the coordinates of the event within the interest region may be an infrared sensor.

The apparatus for detecting the coordinates of the event within the interest region may further include: an image processing unit receiving image information input into the image sensor and processing data.

The image processing unit of the apparatus for detecting the coordinates of the event within the interest region may be configured of a module separate from that of the apparatus for detecting coordinates and receive the image information input to the image sensor through wireless communication.

According to another aspect of the present invention, there is provided a display device including: a display panel being an interest region; a support frame supporting the display panel; and an apparatus for detecting coordinates, including a light source, disposed at one side of the support frame and providing infrared light to the display panel, at least two light receiving units receiving reflected light of an event within the display panel, and one image sensor on which the reflected light passing through the light receiving units are image-formed.

According to another aspect of the present invention, there is provided a security device including: an apparatus for detecting coordinates installed to provide infrared light to a door that is an interest region and including at least two light receiving units receiving reflected light of an event observed on the surface of the door and one image sensor on which the reflected light passing through the light receiving units is image-formed; and an image processing unit receiving the event information in the apparatus for detecting coordinates in a wired or wireless manner and controlling the opening/closing of the door.

According to another aspect of the present invention, there is provided an electronic blackboard including: a board being an interest region; and an apparatus for detecting coordinates installed to provide infrared light to the board and including at least two light receiving units receiving reflected light observed on the surface of the board and one image sensor on which the reflected light passing through the light receiving units is image-formed.

The electronic blackboard according to another aspect of the present invention may further include an image processing unit receiving the event information of the apparatus for detecting coordinates in a wired or wireless manner.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic diagram explaining a principle of an apparatus for detecting coordinates of an event within an interest region according to an exemplary embodiment of the present invention;

FIG. 2 is an enlarged diagram of A of FIG. 1;

FIG. 3 is a schematic diagram explaining a calculation of an apparatus for detecting coordinates of an event within an interest region according to an exemplary embodiment of the present invention;

FIG. 4 is a schematic perspective view of a display device to which an apparatus for detecting coordinates of an event within an interest region according to an exemplary embodiment of the present invention is applied;

FIG. 5 is a schematic perspective view of a security device to which an apparatus for detecting coordinates of an event within an interest region according to an exemplary embodiment of the present invention is applied; and

FIG. 6 is a schematic perspective view of an electronic blackboard to which an apparatus for detecting the coordinates of an event within an interest region according to an exemplary embodiment of the present invention is applied.

### DETAILED DESCRIPTION OF THE PREFERRED EMBODIMENT

Exemplary embodiments of the present invention will now be described in detail with reference to the accompanying drawings. However, the scope of the invention is not limited to the embodiments but other retrogressive inventions or other embodiments included in the scope of the present invention can be easily proposed by those skilled in the art who understand the idea of the present invention by adding, modifying, removing, etc. of another component within the same scope of the present invention and can be construed to be included in the scope of the present invention.

Further, throughout the drawings referenced in the present invention, like components having the same functions within the scope of the same idea will be denoted using the same or similar reference numerals.

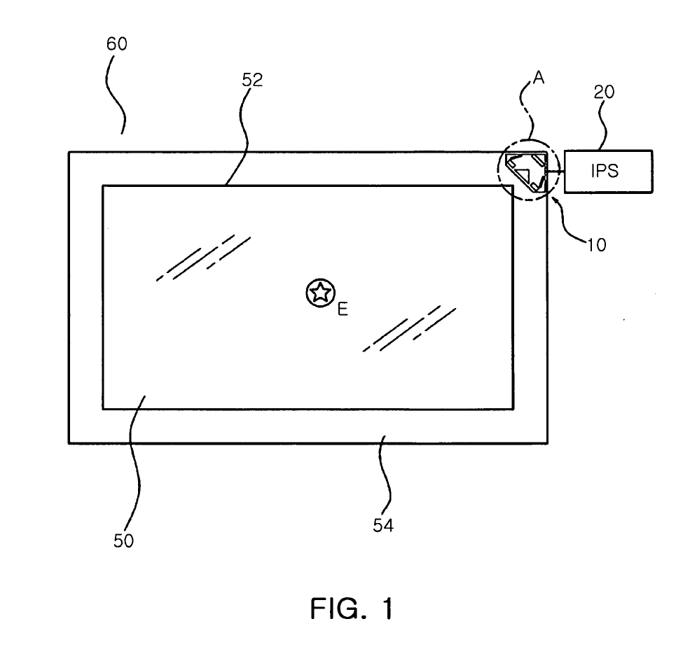

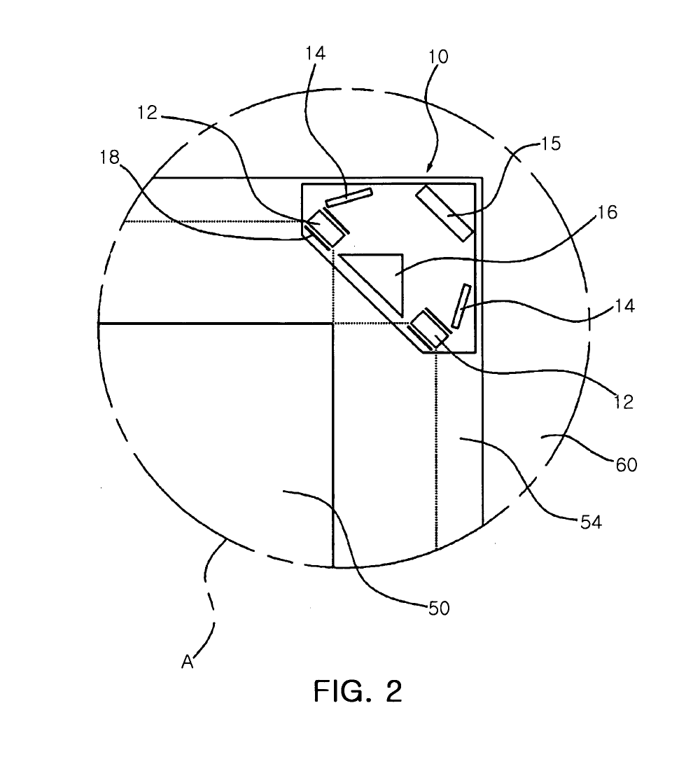

FIG. 1 is a schematic diagram explaining a principle of an apparatus for detecting the coordinates of an event within an interest region according to an exemplary embodiment of the present invention, and FIG. 2 is an enlarged diagram of A of FIG. 1.

Referring to FIGS. 1 and 2, an apparatus 10 for detecting the coordinates of an event within an interest region according to an exemplary embodiment of the present invention is configured of one module, wherein a light source 16, a light receiving unit 12, a reflector 14, and an image sensor 15 may be included inside the module.

The light source 16 defines an interest region 50 of the apparatus 10 for detecting coordinates. The interest region 50 is a region where the apparatus 10 for detecting coordinates obtains coordinates and an optional 2-dimension plane may be an object of the interest region 50 in broad meaning.

The light source 16 may be configured of an infrared illuminant and be provided in plural depending on the area of the interest region 50 or for increasing the life span of the light source. The light emitted from the light source 16 is radially emitted, thereby making it possible to cover the interest region 50. In FIG. 1, the interest region 50 is formed to have a rectangular shape, but may be formed to have various shapes depending on disposed positions, etc. within the apparatus 10 for detecting the coordinates of the light source 16. Herein, the boundary of the interest region 50 is indicated by reference numeral 52, the region where the apparatus 10 for detecting coordinates can be installed is indicated by reference numeral 54, and other non-interest region is indicated by reference numeral 60.

When there is an event E generated in the interest region 50, the light receiving unit 12 absorbs the light reflected from the event E and returned. Two or more light receiving units 12 should be provided at different positions in order to exactly detect the coordinates of the event E in the interest region 50. Herein, the light receiving unit 12 functions as a path that receives the light from the interest region 50, wherein the light receiving unit 12 may be an optical element such as a lens, a prism, etc. The interest region 50 may be equal to a common region of the regions whose light will be absorbed by different light receiving units 12 or be included inside the common region.

Herein, the event E is an action or a situation that is an object of the coordinates measurement to be measured by the apparatus 10 for detecting coordinates and the event E may be defined as an action or a situation that causes a change of an image detected in an image sensor 15 within the apparatus 10 for detecting coordinates.

The infrared light emitted from the light source 16 is reflected from the event E and is received in the light receiving units 12. The reflected light passing through the light receiving units 12 may be refracted onto the reflector 14. The reflector 14 means a medium that reflects or refracts light, such as a mirror or a prism.

At this time, the apparatus 10 for detecting coordinates may include an infrared filter 18 that is disposed in the front or rear of the light receiving unit 12 and passes only a predetermined frequency band of the infrared rays of the light reflected from the event E.

The infrared filter 18 may be coated on or attached to the light receiving unit 12 and be used in order to identify the light receiving unit 12. In other words, the infrared filter 18 may be disposed on any one of the plurality of light receiving units 12 that may exist within the light receiving unit 12 or be disposed on all of them, depending on the intention of a user. Further, the infrared filter 18 may be disposed in the front of, in the rear of, or in the front and rear of the light receiving units 12, having different kinds depending on a predetermined frequency band.

The reflected light refracted on the reflector 14 is image-formed on the image sensor 15. The image sensor 15 may be the infrared sensor, and the image sensor 15 may sense infrared rays and store, transmit, and data-process image information, etc.

Herein, the image sensor 15 is formed as a single, integrated unit and may combine all of the infrared rays of the reflected light passing through the respective light receiving units 12 and store the image information.

The apparatus 10 for detecting coordinates may include an image processing unit 20 that receives the image information input to the image sensor 15 and processes data. Meanwhile, the image processing unit 20 may be configured of a separate module outside the apparatus 10 for detecting coordinates. When the image processing unit 20 is configured of a separate module on the outside, it may receive the image information input to the image sensor 15 through wired or wireless communication.

Hereinafter, when the event E such as a touch, etc. is generated within the interest region 50, a method for detecting the coordinates of the event will be described.

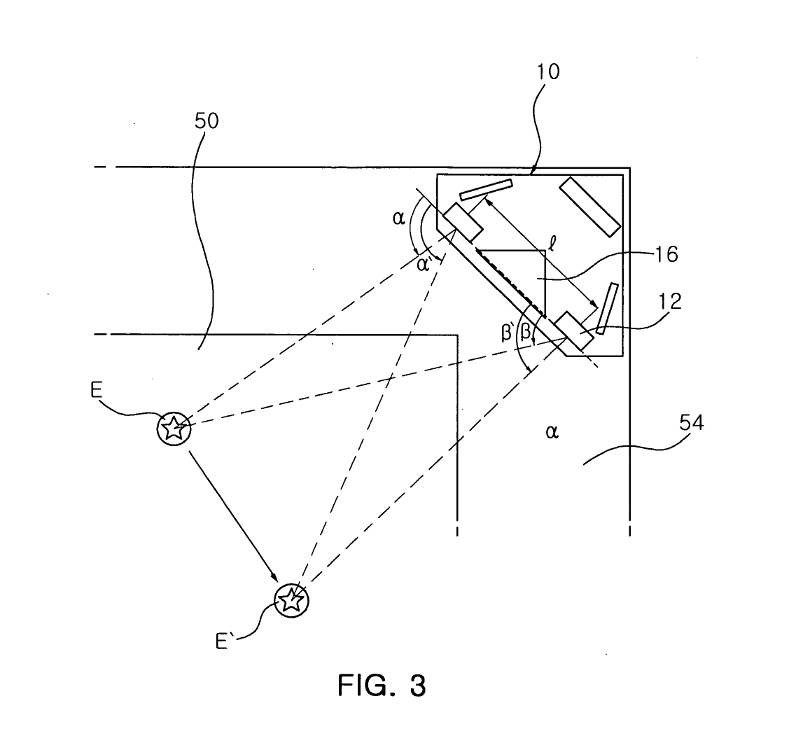

FIG. 3 is a schematic diagram explaining a calculation of an apparatus for detecting coordinates of an event within an interest region according to an exemplary embodiment of the present invention.

Referring to FIG. 3, when the event E such as a touch, etc. is generated within the interest region 50, the infrared light emitted from the light source 16 is reflected by the event E and then absorbed into the respective light receiving units 12.

Herein, the respective light receiving units 12 receive the reflected light of the event E that reflects the infrared light emitted from the light source 16. The respective light receiving units 12 are disposed within the apparatus 10 for detecting coordinates in order that they form a triangle with the event E.

In FIG. 3, the length of an opposite side of the triangle that connects any one points from the respective light receiving units 12 is represented by l, an incident angle to one light receiving unit of the light receiving units 12 thereof is represented by α, and an incident angle to the other light receiving unit of the light receiving units 12 thereof is represented by β.

As described above, the event E and the respective light receiving units 12 form a triangle, and the length l of the opposite side and two angles α and β are provided by the principle of the triangle, thereby making it possible to detect the position of the coordinates.

Further, when the event E is moved, the relative coordinates of a new event E′ can be detected, such that the apparatus 10 for detecting coordinates can detect image information of the event changing in real time, such as movement, drag, appearance, disappearance, etc. of the event.

Hereinafter, various exemplary embodiments, to which the apparatus 10 for detecting coordinates described above is applied, will be described. A display device 100, a security device 200, and an electronic blackboard 300 to which the apparatus 10 for detecting coordinates is applied will be provided in the exemplary embodiments of the present invention by way of example. However, the apparatus 10 for detecting coordinates may also be applied to any devices that require the detection of coordinates.

Further, the apparatus 10 for detecting coordinates applied hereto may cite the technical features of the apparatus 10 for detecting coordinates as described above and therefore, a detailed description thereof will be omitted.

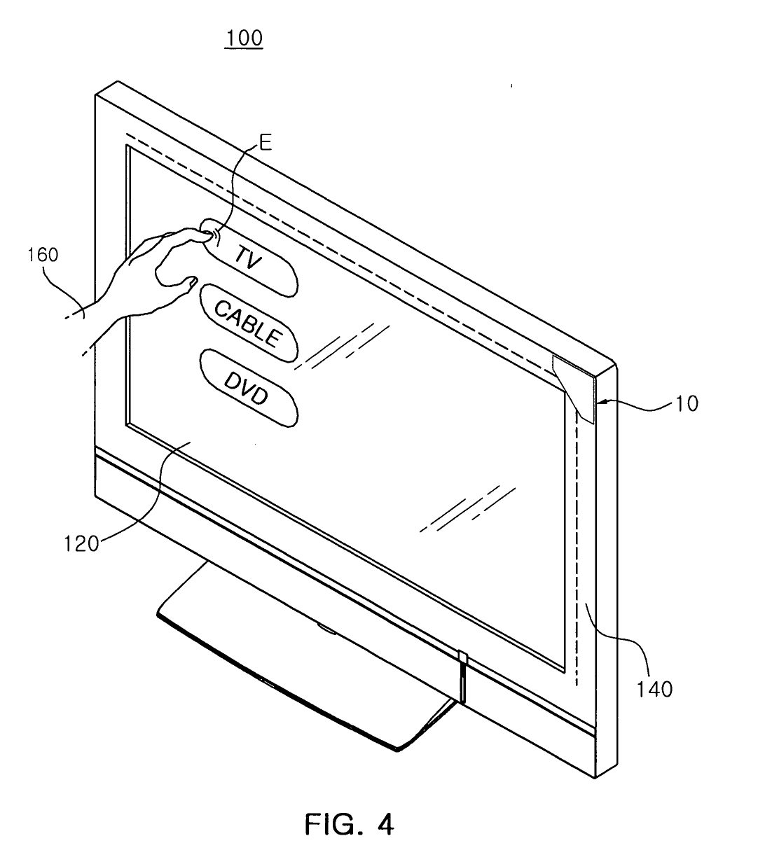

FIG. 4 is a schematic perspective view of a display device to which an apparatus for detecting the coordinates of an event within an interest region according to an exemplary embodiment of the present invention is applied.

Referring to FIG. 4, the display device 100 may be configured to include a display panel 120, a support frame 140, and an apparatus 10 for detecting coordinates.

Herein, the display device 100 is an inclusive term including all devices displaying an image, wherein as the display device, there may be a PDP, a LCD, an OLED, an AMOLED, etc.

The display panel 120 becomes an interest region of the apparatus 10 for detecting coordinates. The display panel 120 is provided with various user interfaces UI. Herein, an event E is generated by an indicating method such as a touch, etc. for the user interface. A finger 160 is illustrated in the present embodiment as the indicating method, but all methods, such as a pen, that can press the user interface can be used.

The information on the coordinates of the event E may be detected by the apparatus 10 for detecting coordinates disposed at one side of the support frame 140. The apparatus 10 for detecting coordinates may be included in the support frame 140.

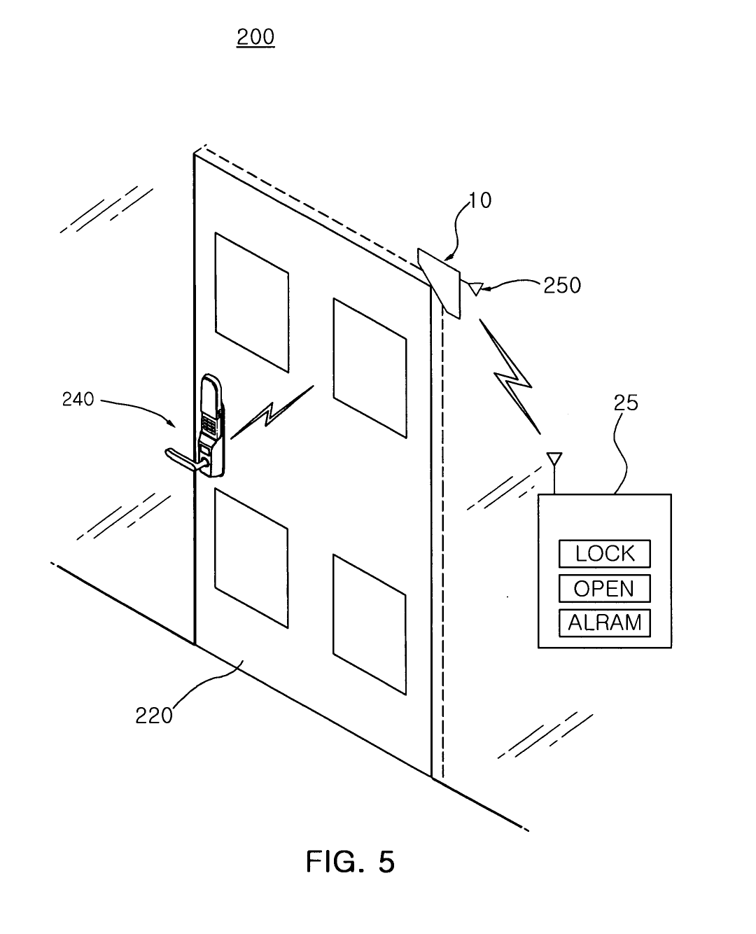

FIG. 5 is a schematic perspective view of a security device to which an apparatus for detecting the coordinates of an event within an interest region according to an exemplary embodiment of the present invention is applied.

Referring to FIG. 5, a security device 200 may be configured to include a door 220, an apparatus 10 for detecting coordinates, and an image processing unit 25.

The door 220 becomes an interest region of the apparatus 10 for detecting coordinates. The apparatus 10 for detecting coordinates is installed so as to provide infrared light toward the door 220. At this time, the apparatus 10 for detecting coordinates may be installed at one side wall of the pillar surface of the door 200.

Herein, an event may be generated as a human or an object stands or passes in front of the door 220 as well as a certain action taking place within the interest region. The apparatus 10 for detecting coordinates may detect the event to provide the information on the event to the image processing unit 25, and the image processing unit 25 may drive the door lock 240 according to the event to open/close the door 200 or sound an alarm.

A case where the information is transmitted in a wireless manner to the apparatus 10 for detecting coordinates by a radio data transmitter 250 is illustrated in the present embodiment, but the data may also be transmitted in a wired manner.

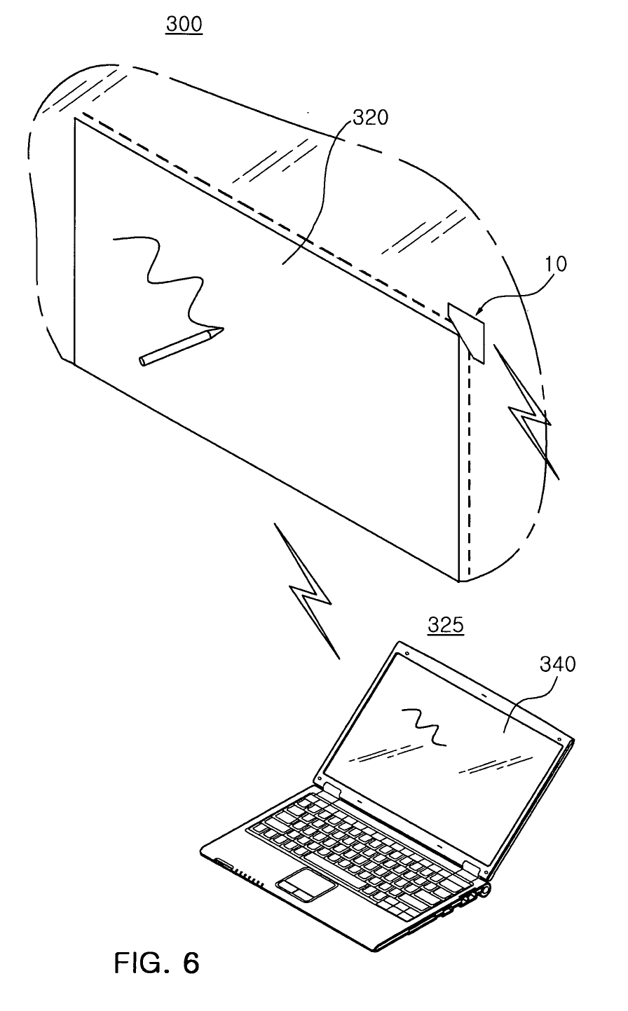

FIG. 6 is a schematic perspective view of an electronic blackboard to which an apparatus for detecting the coordinates of an event within an interest region according to an exemplary embodiment of the present invention is applied.

Referring to FIG. 6, an electronic blackboard 300 may be configured to include a board 320 and an apparatus 10 for detecting coordinates.

Herein, the board 320 is an interest region of the apparatus 10 for detecting coordinates, wherein as the board 320, there may be a simple wall or anything that can be used as a black board.

The apparatus 10 for detecting coordinates may be disposed at one side of the board 320, thereby making it possible to detect image-forming such as text, pictures, etc. written on the board 320.

The data information stored in the apparatus 10 for detecting coordinates may be transmitted to a user information apparatus 325 that is connected in a wired or wireless manner, such as a notebook computer or a smart phone, etc. The transmitted data may be displayed on the display panel 340 as the event (text, pictures, etc.) written on the board 320.

As set forth above, with the apparatus for detecting the coordinates of the event within the interest region, the display device, the security device and the electronic blackboard including the same, according to exemplary embodiments of the invention, the event and the coordinates within the interest region can be detected using a single imaging device, thereby making it possible to reduce installation space and installation time.

Further, the image information sensed through the at least two light receiving units can be processed using one image sensor, thereby making it possible to simplify and speed up the processing.

Further, one imaging device can be produced as a removable set component, thereby making it possible to be used in various applications.

While the present invention has been shown and described in connection with the exemplary embodiments, it will be apparent to those skilled in the art that modifications and variations can be made without departing from the spirit and scope of the invention as defined by the appended claims.

What is claimed is:

1. An apparatus for detecting the coordinates of an event within an interest region, comprising:
a light source limiting an interest region;
at least two light receiving units receiving reflected light of an event within the interest region;
a reflector refracting the reflected light received in the light receiving units; and
one image sensor on which the reflected light refracted on the reflector is image-formed,
wherein the apparatus for detecting coordinates is configured of one module

2. The apparatus for detecting the coordinates of the event within the interest region of claim 1, wherein the light source includes an infrared illuminant.

3. The apparatus for detecting the coordinates of the event within the interest region of claim 1, wherein the light receiving unit functions as an inlet that inputs the reflected light to the image sensor and may include an optical element.

4. The apparatus for detecting the coordinates of the event within the interest region of claim 1, further comprising an infrared filter disposed in the front or the rear of the light receiving unit and admitting only a predetermined frequency band of the infrared rays of the reflected light reflected from the event

5. The apparatus for detecting the coordinates of the event within the interest region of claim 4, wherein the infrared filter is coated or attached to the surface of the light receiving unit.

6. The apparatus for detecting the coordinates of the event within the interest region of claim 1, wherein the image sensor is an infrared sensor.

7. The apparatus for detecting the coordinates of the event within the interest region of claim 1, further comprising an image processing unit receiving image information input to the image sensor and processing data.

8. The apparatus for detecting the coordinates of the event within the interest region of claim 7, wherein the image processing unit is configured of a module which is separate from that of the apparatus for detecting coordinates and receives the image information input to the image sensor through wireless communication.

9. An apparatus for detecting the coordinates of an event within an interest region, comprising:
a light source including an infrared illuminant;
at least two light receiving units receiving reflected light of an event that reflects infrared light emitted from the light source and disposed so as to form a triangle with the event;
a reflector disposed at the rear of the light receiving unit so as to refract the reflected light received in the light receiving units; and
one image sensor on which the reflected light refracted on the reflector is image-formed.

10. The apparatus for detecting the coordinates of the event within the interest region of claim 9, wherein the light receiving unit functions as an inlet that inputs the reflected light to the image sensor and may include an optical element.

11. The apparatus for detecting the coordinates of the event within the interest region of claim 9, further comprising an infrared filter disposed in the front or the rear of the light receiving unit and admitting only a predetermined frequency band of the infrared rays of the reflected light reflected from the event.

12. The apparatus for detecting the coordinates of the event within the interest region of claim 11, wherein the infrared filter is coated or attached to the surface of the light receiving unit.

13. The apparatus for detecting the coordinates of the event within the interest region of claim 9, wherein the image sensor is an infrared sensor.

14. The apparatus for detecting the coordinates of the event within the interest region of claim 9, further comprising an image processing unit receiving image information input into the image sensor and processing data.

15. The apparatus for detecting the coordinates of the event within the interest region of claim 14, wherein the image processing unit is configured of a module separate from that of the apparatus for detecting coordinates and receives the image information input to the image sensor through wireless communication.

16. A display device comprising:
a display panel being an interest region;
a support frame supporting the display panel; and
an apparatus for detecting coordinates, including a light source, disposed at one side of the support frame and providing infrared light to the display panel, at least two light receiving units receiving reflected light of an event within the display panel, and one image sensor on which the reflected light passing through the light receiving units are image-formed.

17. A security device comprising:
an apparatus for detecting coordinates installed to provide infrared light to a door that is an interest region and including at least two light receiving units receiving reflected light of an event generated in the door and one image sensor on which the reflected light passing through the light receiving units is image-formed; and
an image processing unit receiving the event information in the apparatus for detecting coordinates in a wired or wireless manner and controlling the opening/closing of the door.

18. An electronic blackboard comprising:
a board being an interest region; and
an apparatus for detecting coordinates installed to provide infrared light to the board and including at least two light receiving units receiving reflected light generated in the board and one image sensor on which the reflected light passing through the light receiving units is image-formed.

19. The electronic blackboard of claim 18, further comprising an image processing unit receiving the event information of the apparatus for detecting coordinates in a wired or wireless manner.
